(19) United States
(12) Patent Application Publication
(10) Pub. No.: US 2007/0184180 A1
(43) Pub. Date: Aug. 9, 2007

(54) CATHODOLUMINESCENT SCREEN WITH A COLUMNAR STRUCTURE, AND THE METHOD FOR ITS PREPARATION

(75) Inventors: Evgeny Invievich Givargizov, Moscow (RU); Ljudmila Alexandrovna Zadorozhnaya, Moscow (RU); Alla Nikolaevna Stepanova, Moscow (RU); Naum Petrovich Soshchin, Fryazino (RU); Nikolai Nikolaevich Chubun, Fryazino (RU); Mikhail Evgenievich Givargizov, Moscow (RU)

Correspondence Address: KNOBBE MARTENS OLSON & BEAR LLP, 2040 MAIN STREET, FOURTEENTH FLOOR, IRVINE, CA, 92614, US

(73) Assignee: Evgency Invievich Givargizov, Moscow (RU)

(21) Appl. No.: 11/735,950

(22) Filed: Apr. 16, 2007

Related U.S. Application Data
(63) Continuation of application No. 09/530,512, filed on Jun. 26, 2000.

(30) Foreign Application Priority Data
Oct. 27, 1997 (RU) 97117737
Dec. 31, 1997 (RU) 97122024

(51) Int. Cl. B05D 5/12; C23C 14/00

(52) U.S. Cl. 427/64; 427/523

(57) ABSTRACT

A cathodoluminescent mosaic screen on a light-transparent substrate wherein the light-emitting components of the screen are implemented as light-guiding single-crystalline columns. A method for preparation of the screen by vapor deposition of the luminescent material onto the substrate coated by a localized liquid phase has been proposed.

### FIELD OF THE INVENTION

The present invention relates to the area of electronic materials and to microelectronics, including vacuum microelectronics, in particular to devices based on field emission, such as field-emission displays, vacuum fluorescent displays, cathodeluminescent lamps, etc.

### PRIOR ART

The existing luminescent screens are produced, as a rule, in the shape of crystalline films that are prepared, for example, by deposition from a vapor phase onto smooth, for example, glass substrate.

For the deposition, techniques of evaporation of materials in vacuum, of sublimation, of chemical transport, of cathode sputtering, etc, are used.

In all the techniques, the nucleation of the crystalline luminescent materials (phosphors) occurs in a non-controlling manner, homogenously or heterogeneously, on a smooth structure-less substrate. At that case, the phosphors are usually a collection of tiny (micron and/or submicron) crystalline grains, usually isometric, approximately spherical shape superposed one onto another (FIG. 1). In such a system, the light generated in a crystalline grain (i.e., designated by a cross) is repeatedly scattered in the labyrinth of surrounding phosphor grains. This phenomenon deteriorates the resolution of the screen.

One more problem relates to the fact that in the film screen, consisting of the crystalline grains, do not all the space is filled by the phosphor. This decreases the effectivity of the screen and deteriorates its thermo- and electroconductivity.

In addition, such screens have a bad adgesion to substrates because the approximately-spherical crystalline grains have only point contacts with the substrates.

In the patent [1], single-crystalline (plate-like or epitaxial-layer) materials are used as phosphors. This improves reproducibility of characteristics of the screen and increases its effectivity (the ratio of the light energy to the energy expended for the light excitation). However, at such a case, the emitting light propagates along the plate (or along the epitaxial layer) of the phosphor; this deteriorates the resolution and the effectivity of the screen.

Another patent [2] supposes localized deposition of a phosphor from a diluted solution or suspension by spinning into holes, side walls of the holes being metallized in order to exclude penetration of the light into neighbor areas of the luminescent screen. However, at this case, contrast of the image is increased for only 50%, in other words, scattering of the light along the luminescent screen is not excluded.

These drawbacks can be eliminated if the luminescent screen is made of columnar crystallites that have elongated shape whose elongation direction is approximately perpendicular to the plane of the screen. Such an idea is realized in the design described in the patent [3]. At such a case the light excitated at columnar crystallites of the phosphor propagates in the elongation direction of the crystallites, the crystallites being acting as light-guides. However, the method for preparation of such screens by melt crystallization is not suitable for many practically-important cases, e.g., for thin (0.1-1 micrometer thickness) flat luminescent screen used in field-emission displays.

In the patent [4], a screen with columnar crystals has been proposed where an insert of non-luminous black material adjacent to the columnar crystals was placed. Such an insert is able to increase an image contrast of the columns that are directly adjacent to the insert, while other columns that are not adjacent (are not contacted) to the insert are not able to increase their contrast. In addition, patent [4] does not give a method for preparation of such a screen.

In this invention, a more optimized design of the screen is proposed. In addition, a technology for preparation of the screen is proposed.

### SUMMARY OF THE INVENTION

A screen with columnar structure is proposed where each column is surrounded by a gap coaxial to the column, the gaps are filled by an electroconductive non-light-emitting medium. Outer butt-ends of the columns are coated by a light-emitting luminescent layer, thickness of the layer being smaller than height of the columns for at least one order of magnitude. The luminescent layer can be epitaxial in respect to the columns.

A method for preparation of the luminescent screens is proposed in this invention, too. The method consists in vapor deposition of the luminescent material where an intermediate substance, that is other than the luminescent material and that forms a liquid phase at the crystallization temperature, is firstly deposited on the substrate. After that, the luminescent material is deposited on such a substrate. Thickness of the intermediate substance is more than 10 nanometers and smaller than 1 micrometer. The liquid phase is formed at a contact interaction of the intermediate substance with the substrate.

The intermediate substance is formed by more than one chemical elements. At least one of the chemical element is operating as an luminescent activator or co-activator. The activator or co-activator is introduced into the luminescent material by means of ion implantation.

A microrelief of inhomogenities in structure and/or chemical composition is created on the substrate, the inhomogenities being of regular character, in particular, of crystallographically-symmetric character.

The luminescent material is coated by a thin layer of a material that is transparent for electrons. In particular, diamond or diamond-like material serve as the transparent material.

### A BRIEF DESCRIPTION OF THE FIGURES

FIG. 1. A scheme of a standard cathodoluminescent screen that is formed by a film of approximately isometric crystalline grain.

FIG. 2. A scheme of a cathodoluminescent screen formed by a film, that consists of columns approximately perpendicular to substrate.

FIG. 3. A scheme of propagation of light beams in the film shown in FIG. 2.

FIG. 4. A SEM micrograph of a cleavage cross-section of a continuous film consisting of the columns.

FIG. 5. A scheme of the cathodoluminescent screen with columnar structure that is bombarded by electrons. The shaded upper parts of the columns show level to which the electrons penetrate and where the light is excited.

FIG. 6. A scheme of the cathodoluminescent screen. The upper butt-ends of the screen are coated by a light-emitting luminescent layer.

FIG. 7. A scheme of the cathodoluminescent screen formed of columns with gaps between them.

FIG. 8. A SEM micrograph of the film that consists of columns with gaps between them (top view). The mosaic structure of the screen is seen.

FIG. 9. A scheme of the cathodoluminescent screen shown in FIGS. 7 and 8. The gaps are filled with an electroconductive non-emitting medium.

### BEST VERSION FOR THE REALIZATION OF THE INVENTION

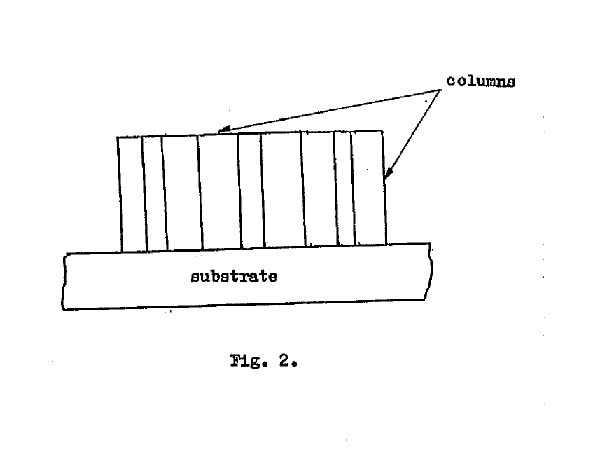

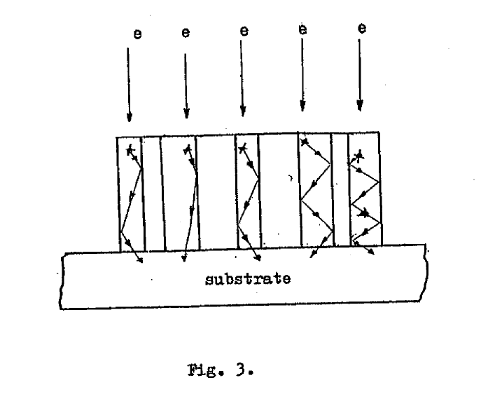

The cathodoluminescent screen with columnar structure, as it was proposed at the prior art, is illustrated in FIGS. 2 and 3.

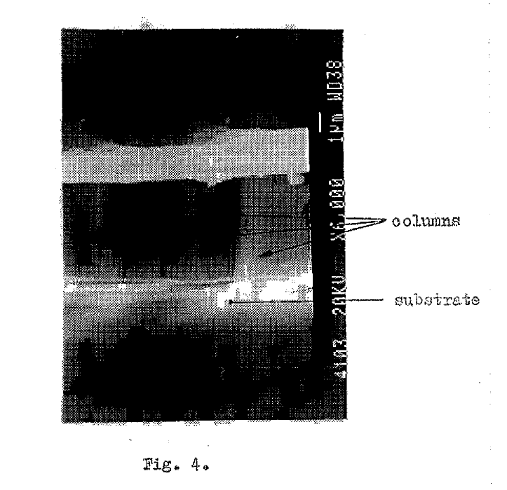

The cathodoluminescent screen, as it is proposed here, is illustrated in FIGS. 4 to 9.

Typical height of the columns, as it is shown in FIG. 4, is about 5 micrometers. Typical height-to-diameter ratio of the columns ranges from 1:1 to 100:1.

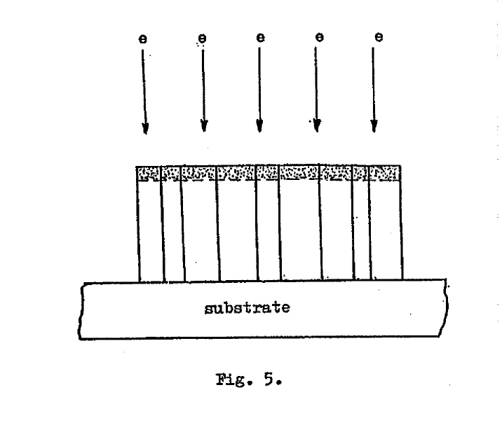

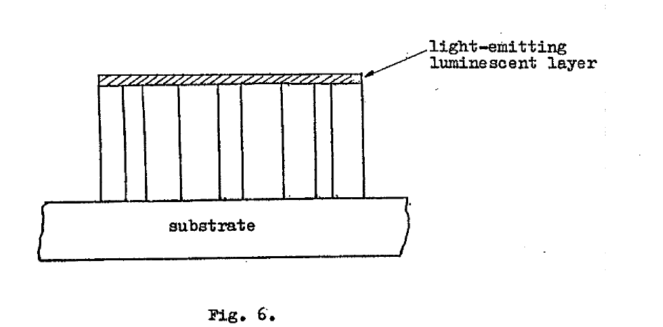

An accelerated electron beam from a flat cathode, as it is usually considered in field-emission displays, is incident on the screen and penetrates into a surface layer (FIG. 5). At typical acceleration voltages of the field-emission displays (for example, 1 to 3 kV) the penetration thickness is about 100 nanometers (shown schematically in FIG. 5 as a shadowed layer). Accordingly, it is proposed to implement the screen as a columnar structure coated by a light-emitting luminescent layer (shown in FIG. 6).

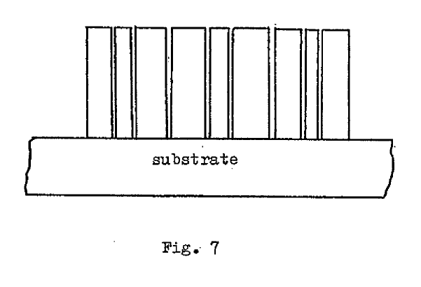

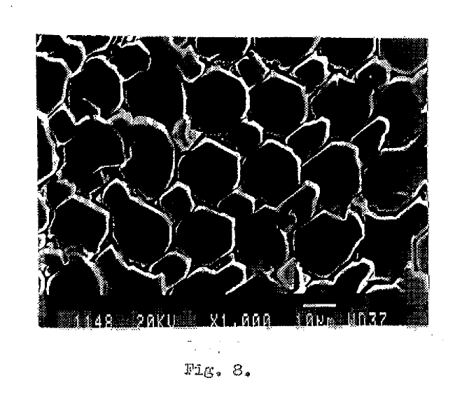

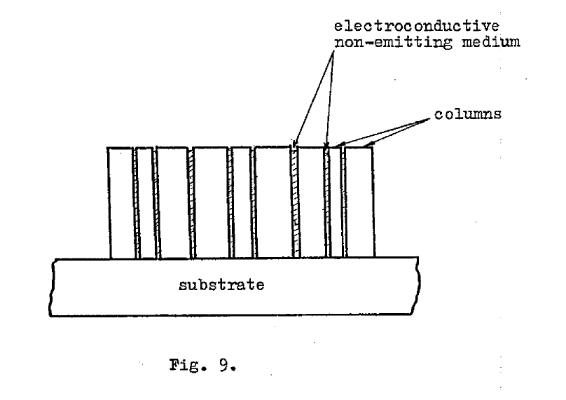

The columns are surrounded by gaps (“trenches”) coaxial to the columns. An elongated cross-section scheme of the columnar structure is shown in FIG. 7. A corresponding scanning electron micrograph of the screen (top-view) is shown in FIG. 8. As is seen, the columns are surrounded by gaps (“trenches”). The gaps are filled by an electroconductive non-light-emitting medium has the coefficient of light absorption in respect to the emitting light more than 20%. A scheme of the filled screen is shown in FIG. 9. The filling ensures a conductivity of the screen and, in such a way, excludes charging phenomena when the luminescent screen is working in a cathodoluminescent mode.

These screens are featured by some advantages, especially in respect to low-voltage field-emission displays.

1. By a high light and energetic output that is caused by its design. Owing to the total internal reflection from the walls of the columns, a light-guide effect takes place: the light propagates preferentially along the columns, do not passing beyond columns and do not passing into neighbour columns.

2. By a low light scattering during the light propagation along the columns. This determines a high resolution of the design. It is equal to the number of the light-emitting components per a length unit.

3. By a high adgesion to the transparent substrate, to which the columns are fixed by their butt-ends, i.e., the light-emitting components contact to the substrate by a large area. This is especially important for diode-type field-emission displays where large gradients of the electric field are able to break screen particles off the substrate.

The advantages of the cathodoluminescent screens having the columnar structure are realized here by a proposed technology for their production. The technology is based on chemical or physical vapor deposition, a participation of a liquid phase in the deposition process being of principal importance. An effectivity of the technology is illustrated in FIG. 4 where the columnar structure of the luminescent material cadmium sulphide is shown.

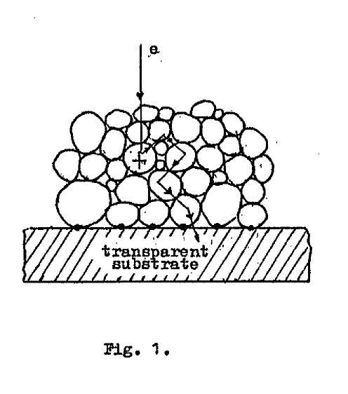

It is to underline principal idea of the proposed design of the cathodoluminscent screen: the propagation direction of light in each columnar component is paraxial (parallel) to the direction of the primary electron beam, that excites the light (see FIG. 3), whereas in the known (standard) screens, formed by superposition of approximately-isometric grains, the light excited by the cathodoluminescence can propagate not only paraxially with the electron beam but also perpendicularly to it, or in any arbitrary direction in respect to the electron beam (see FIG. 1).

As the design of the columnar screen was realized and used in concrete electron devices, some not-evident its advantages were found.

(a) Luminescence brightness of different grains (columns in this case) becomes more uniform. In the standard cathodoluminescent screens, the brightness of various grains differs significantly (up to 50% at distances 25-30 micrometers) due to differences in sizes of emitting grains; this deteriorates transfer and fixation of qualitative images.

(b) Electrical and heat power dissipation by the columnar phosphors increases significantly (5 to 10 times) in comparison with the standard cathodoluminescent screens.

(c) The “burning out” of the columnar screens at an unexpected switching off the electron beam scanning is practically eliminated. In the standard cathodoluminescent screens the power sufficient for irreversible burning out of the screens is usually 0.1 W/element (here the element is an image element, i.e., a pixel), whereas preliminary testings of the proposed columnar screen indicate to increase of the parameter up to 1 W/element (here the element is a column).

(d) The background image contrast at an illumination with intensive light sources (sun, electric lamp, etc) is increased. Standard cathodoluminescent screens have the contrast value k=b_{image}/b<5, where b is the brightness of background, b_{image} is the brightness of the pixel. Testings of the screens based on the proposed columnar phosphors show the values k>10 to 20.

A significant electric charge accumulated by standard screens is not completely removed even by metallic (for example, aluminium) coatings 0.1-0.5 μm in thickness that are usually formed on the surface of the standard cathodoluminescent screens. This manifests itself in numerous discharges that disturb a stable work of electron devices. The columns are surrounded by gaps coaxial to the columns (see FIGS. 7 to 9). The remainder of the substrate area and all other volume of the screen are filled by an electroconductive non-light-emitting medium that has the coefficient of light absorption in respect to the emitting light more than 20%.

It is to note that the above-mentioned advantages of the columnar screens manifest thyself both in experimental (10×10 mm) and consumer (25×25 or 75×75 mm) sizes of the screens. In other words, the unique parameters of the proposed structure do not depend on the sizes.

Changes of cross-sectional sizes of the light-emitting elements have been studied in respect to characteristics of the screens in general. At the cross-sectional size of the light-emitting elements about 1 μm and the pitch distance about 2 μm a light-emitting structure contained more than 2.5.10⁷ cm⁻² light-emitting elements has been prepared. The parameters are superior in resolution respectively to all known screens. It has been also found that the columnar structures with pitches 20 μm, at a total number of the columns 2.5.10⁵ cm⁻², can have important applications as screens of electron-beam devices and of transducers.

The procedure for filling of the gaps around the columns with the electroconductive non-light-emitting medium consists in a dipping of the columnar structure into a melt of suitable oxides and/or sulphides. Another approach consists in impregnation of columnar structures in low-melting-point compounds. As such, not only oxides like B₂O₃ (melting point 450° C.), V₂O₅ (melting point 670° C.), CdO (826° C.), PbO₂ (290° C.), Bi₂O₃ (817° C.), but also sulphides SnS (882° C.), Sb₂S₃ (550° C.) were used. In addition, metallic eutectics like Cd—Bi—Pb—Sn (melting point 65° C.) and Pb—Sn were tested, too. All the mentioned compositions absorb the light in the spectral subrange 420 to 760 nanometers, therefore it is possible, in the mosaic columnar structure, to increase significantly the contrast value owing to an increased absorption of the side emission of the columns and of an external light passing through the transparent substrate.

It was studied an influence of the electroconductive medium on the luminescent properties of the screen formed by the mosaic columnar structure. In the case of the filling of the gaps between the columns by the eutectic metallic phase Cd—Bi—Pb—Sn, the resistivity of the filling phase was 1 to 20 Ohm.cm at the value of the optical absorption >10⁵ cm⁻¹. At the ratio of the substrate area, coated by the columns, to the area of the filling medium 5:1, the coefficient of light reflection from the front surface of the screen is 20%, while a similar columnar structure, that was not filled by the electroconductive medium, reflects 45 to 60% of incident light.

Relationships between the height of the columns and the height level of the light-absorbing phase were not studied. In some preliminary experiments, the relationship was 2:1. Even such a value provided run-off the electron current densities 1 to 10 A/cm².

The columnar elements of the mosaic screen can have an additional coating by metallic (Al or Ag) mirror transparent for electron beams with energies >5 keV.

### REFERENCES

1. G. W. Berskstresser and C. D. Brandle, Cathode ray tube with single crystal targets, European Patent Application 232586, CI. H01 J 29/26 (1987).
2. V. Duchenois, M. Fouassier, and H. Baudry, Ecran cathodoluminescent incruste a cavities restaurees et tube de visualisation utilisant un tei ecran, European Patent Application 170310, CI. H01 J 29/24 (1988).
3. B. Cockayne, Cathode ray tube phosphor layers, European Patent Application 062993, CI. H01 J 29/20 (1982).
4. M. Kakuki, Fluorescent screen of electron tube, Japanese Patent 55088245, CI. H01 J 29/20 (1980).

What is claimed:

1. A method of preparing luminescent screens, comprising:
providing a substrate having columns of a single-crystalline material, the single-crystalline material having a predetermined crystallization temperature;
depositing an intermediate material on the substrate, wherein the intermediate material forms liquid at the crystallization temperature of the single-crystalline material; and depositing a luminescent material on the substrate, wherein the luminescent material is different from the intermediate material.

2. The method according to claim 1, wherein a thickness of the intermediate material is more than 10 nanometers and less than 1 micrometer.

3. The method according to claim 1, wherein the intermediate material is liquid at a contact interaction of the intermediate material with the substrate.

4. The method according to claim 1, wherein the intermediate material includes more than one chemical element.

5. The method according to claim 2, wherein the intermediate material includes more than one chemical element.

6. The method according to claim 4, wherein at least one of the chemical elements acts as a luminescent activator or co-activator.

7. The method according to claim 1, further comprising forming at least one of a predetermined structure and a predetermined chemical composition on the substrate.

8. The method according to claim 1, further comprising forming a predetermined regular structure on the substrate.

9. The method according to claim 1, further comprising forming a predetermined structure on the substrate, wherein the structure has a crystallographically-symmetric character.

10. The method according to claim 6, wherein the activator or co-activator is introduced into the luminescent material by means of ion implantation.

11. The method according to claim 9, wherein the luminescent material is coated by a thin layer of a material transparent for electrons.

12. The method according to claim 11, wherein the transparent material includes a diamond or diamond-like material.
